(19) United States
(12) Patent Application Publication
(10) Pub. No.: US 2013/0249087 A1
(43) Pub. Date: Sep. 26, 2013

(54) ELECTRONIC COMPONENT AND MANUFACTURE METHOD THEREOF

(71) Applicant: FUJITSU LIMITED, Kawasaki-shi (JP)

(72) Inventors: Kimio Nakamura, Kawasaki (JP); Takayoshi Matsumura, Kawasaki (JP); Yoshiyuki Satoh, Kawasaki (JP); Kuniko Ishikawa, Kawasaki (JP); Kenji Kobae, Kawasaki (JP)

(73) Assignee: FUJITSU LIMITED, Kawasaki-shi (JP)

(21) Appl. No.: 13/867,847

(22) Filed: Apr. 22, 2013

Related U.S. Application Data
(62) Division of application No. 12/822,656, filed on Jun. 24, 2010.

(30) Foreign Application Priority Data
Jun. 26, 2009 (JP) 2009-152817

(51) Int. Cl. H01L 23/498

(52) U.S. Cl. CPC H01L 23/49811
USPC 257/737

(57) ABSTRACT

An electronic component includes a package substrate, a plurality of conductive pads, an insulating material and a semiconductor device. The plurality of conductive pads is disposed on the package substrate. The insulating material is disposed between the plurality of conductive pads. The insulating material includes a top surface located on an identical plane to an upper surface of the plurality of conductive pads. The semiconductor device includes a conductive bump aligned on a corresponding conductive pad of the plurality of conductive pads.

### CROSS-REFERENCE TO RELATED APPLICATION

This application is based upon and claims the benefit of priority of Japanese Patent Application No. 2009-152817, filed on Jun. 26, 2009, the entire contents of which are incorporated herein by reference.

### FIELD

The embodiments discussed herein relate to an electronic component and a manufacture method thereof.

### BACKGROUND

A plurality of conductive pads is arranged on the undersurface of a large scale integration (LSI) device. The LSI device is mounted on a package substrate. In order to mount the LSI device on the package substrate, for example, gold bumps are individually attached on the conductive pads of the LSI device in advance. In such a case, the gold bumps are individually positioned on the conductive pads which are arranged on the surface of the package substrate. A gap between the undersurface of the LSI device and the surface of the package substrate is filled with an underfill material that is a thermosetting resin material. The underfill material is heated to a predetermined temperature while the LSI device is pressed against the package substrate. When the underfill material cures, the LSI device is fixed to the package substrate (see, for example, Japanese Laid-Open Patent Applications 2003-243447, 2004-320043, and 2005-20004).

In such a case, the upper surface of the conductive pad is uneven with respect to a surface of the package substrate. Accordingly, when a conductive bump of the LSI device is not accurately mounted on the corresponding conductive pad of the package substrate, the conductive bump may slip from the conductive pad down to the surface of the package substrate. As a result, an electric connection between the conductive bump and the corresponding conductive pad of the package substrate may fail. Also, the conductive bump may be mounted on an adjacent conductive pad to establish an abnormal electrical connection. If the LSI device is fixed to the package substrate with the underfill material in this state, a defective product is expected.

### SUMMARY

According to an embodiment of the invention, an electronic component includes a package substrate, a plurality of conductive pads, an insulating material and a semiconductor device. The plurality of conductive pads is disposed on the package substrate. The insulating material is disposed between the plurality of conductive pads. The insulating material includes a top surface located on an identical plane to an upper surface of the plurality of conductive pads. The semiconductor device includes a conductive bump aligned on a corresponding conductive pad of the plurality of conductive pads.

It is to be understood that both the foregoing general description and the following detailed description are exemplary and explanatory, and are not restrictive of the invention, as claimed.

### BRIEF DESCRIPTION OF DRAWINGS

The above-described and other features of the invention will become apparent from the following description of the embodiments in conjunction with the accompanying drawings, wherein:

FIG. 1 is a schematic perspective view illustrating an external view of an example of an electronic apparatus according to the present invention;

FIG. 2 is a schematic cross-sectional view of an electronic component according to a first embodiment of the present invention;

FIG. 3 is a view taken along the line 3-3 of FIG. 2;

FIG. 4 is a schematic partial perspective view illustrating an electronic component according to the first embodiment;

FIG. 5 is a schematic perspective view of a package substrate according to the first embodiment;

FIG. 6 illustrates a process of forming conductive pads and wiring patterns according to the first embodiment;

FIG. 7 illustrates a process of applying a solder resist according to the first embodiment;

FIG. 8 is a perspective view illustrating a process of forming a solder resist having a predetermined pattern according to the first embodiment;

FIG. 9 illustrates a process of performing wet blast upon a solder resist according to the first embodiment;

FIG. 10 is a cross-sectional view illustrating a process of forming a solder resist having a predetermined pattern according to the first embodiment;

FIG. 11 is a view taken along the line 11-11 of FIG. 10;

FIG. 12 illustrates a process of forming a depression in the surface of a package substrate according to the first embodiment;

FIG. 13 illustrates a process of mounting a semiconductor device on a package substrate according to the first embodiment;

FIG. 14 illustrates a process of mounting a semiconductor device on a package substrate according to the first embodiment;

FIG. 15 illustrates a process of mounting a semiconductor device on a package substrate according to the first embodiment;

FIG. 16 illustrates a process of mounting a semiconductor device on a package substrate according to a comparative example;

FIG. 17 illustrates a process of mounting a semiconductor device on a package substrate according to the comparative example;

FIG. 18 illustrates the warpage of a package substrate in response to a temperature increase during an operation according to the first embodiment;

FIG. 19 illustrates the warpage of a package substrate in response to a temperature increase during an operation according to the comparative example;

FIG. 20 is a schematic cross-sectional view of an electronic component according to a second embodiment of the present invention;

FIG. 21 is a view of the electronic component depicted in FIG. 20 taken along the line 21-21;

FIG. 22 illustrates a process of forming conductive pads and wiring patterns according to the second embodiment;

FIG. 23 illustrates a process of forming conductive pads and wiring patterns according to the second embodiment;

FIG. 24 illustrates a process of forming a protrusion portion on a conductive pad according to the second embodiment;

FIG. 25 illustrates a process of forming a protrusion portion on a conductive pad according to the second embodiment;

FIG. 26 illustrates a process of forming a protrusion portion on a conductive pad according to the second embodiment;

FIG. 27 is a schematic cross-sectional view of an electronic component according to a third embodiment of the present invention; and

FIG. 28 is a schematic cross-sectional view of an electronic component according to a fourth embodiment of the present invention.

### DESCRIPTION OF EMBODIMENTS

Various embodiments of the present invention will be described below with reference to the accompanying drawings.

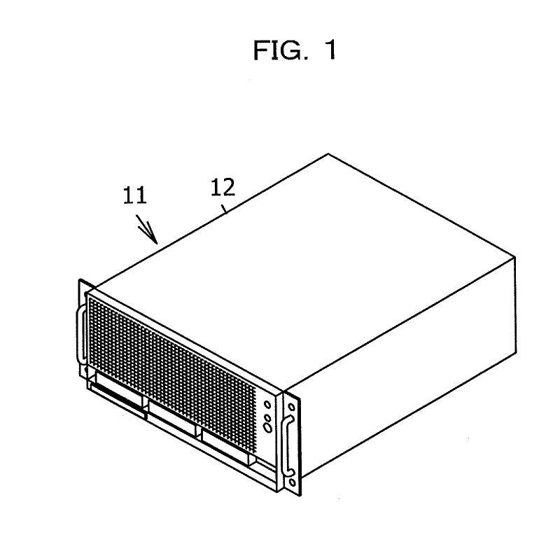

FIG. 1 schematically illustrates an external view of a server computer apparatus 11 that is an example of an electronic apparatus. The server computer apparatus 11 is provided with an enclosure 12 having an inner storage space. A motherboard is disposed in the inner storage space. The motherboard includes, for example, an electronic component and a main memory. The electronic component performs various pieces of computation processing on the basis of, for example, a software program or data temporarily stored in the main memory. The server computer apparatus 11 is mounted on, for example, a rack.

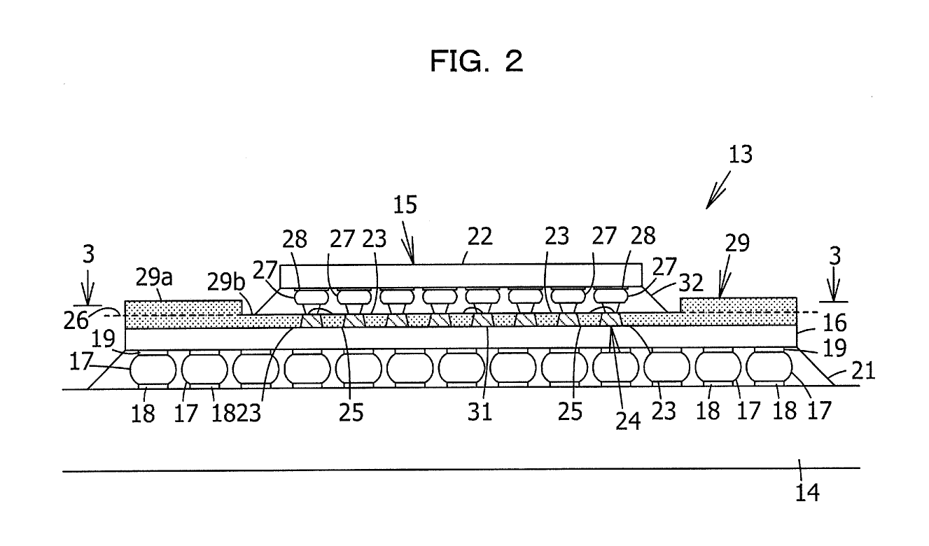

FIG. 2 schematically illustrates a configuration of an exemplary printed board unit that is a motherboard 13. The motherboard 13 includes a printed writing board 14. On the surface of the printed writing board 14, an electronic component according to a first embodiment of the present invention, which is a large-scale integrated circuit (LSI) package 15, is disposed. The LSI package 15 includes a package substrate 16. The package substrate 16 is a resin board formed of, for example, a glass epoxy resin. In order to form the package substrate 16, glass fiber is impregnated with an epoxy resin. The package substrate 16 has a polygonal outer contour such as a rectangular contour.

The LSI package 15 includes a plurality of conductive bumps 17. The conductive bumps 17 are disposed on the surface of the printed writing board 14 so that the conductive bumps 17 are inside the contour of the package substrate 16. The conductive bumps 17 are composed of balls included in a ball grid array (BGA). The conductive bumps 17 are formed of a solder material. For example, the solder material may be a lead-free solder. An example of such a lead-free solder is an Sn—Ag—Cu alloy. Each of the conductive bumps 17 connects one of conductive pads 18 arranged on the surface of the printed writing board 14 and a corresponding one of conductive pads 19 arranged on the undersurface of the package substrate 16 to each other. There is a one-to-one relationship between the conductive pads 18 and the conductive pads 19.

The conductive bumps 1.7 are sealed on the printed writing board 14. The space between the surface of the printed writing board 14 and the undersurface of the package substrate 16 in which the conductive bumps 17 are present is filled with an underfill material 21, which is a solid sealant. The underfill material 21 is an insulating and thermosetting resin material, for example, an epoxy resin. The underfill material 21 fixes the LSI package 15 to the surface of the printed writing board 14. As a result, the LSI package 15 and the printed writing board 14 are electrically connected to each other.

On the surface of the package substrate 16, an electronic component, that is, an LSI device 22, is disposed. The LSI device 22 has a polygonal outer contour such as a rectangular contour. The LSI device 22 is formed of, for example, silicon. On the surface of the package substrate 16, a plurality of conductive pads 23 are arranged. The conductive pads 23 arranged along each side of the contour of the LSI device 22 form a pad group 24. The pad groups 24 individually extend along sides of the contour of the LSI device 22 and sides of the contour of the package substrate 16. In each of the pad groups 24, the conductive pads 23 are arranged at regular intervals.

The cross sections of the conductive pads 23 specified in a vertical direction orthogonal to the surface of the package substrate 16 have a trapezoidal shape. Accordingly, when the height from the surface of the package substrate 16 is increased, the side surfaces of each of the conductive pads 23 get closer to each other. Each of the conductive pads 23 has a flat pad surface 25 at an upper end thereof. The pad surfaces 25 are disposed in a common imaginary plane 26. The imaginary plane 26 is parallel to, for example, the surface of the package substrate 16. The conductive pads 23 are formed of, for example, a conductive material such as copper. On a copper surface, a nickel plating film or a gold plating film is formed.

Conductive bumps 27 are individually positioned on the pad surfaces 25 of the conductive pads 23. Conductive pads 28 arranged on the undersurface of the LSI device 22 are individually received on the conductive bumps 27. There is a one-to-one relationship between the conductive pads 28 and the conductive pads 23. The conductive bumps 27 are formed of a conductive material such as gold. The conductive bumps 27 are individually bonded to the conductive pads 28 by, for example, ultrasonic bonding. On the other hand, the conductive bumps 27 are individually received on the pad surfaces 25 of the conductive pads 23. The conductive pads 28 are formed of, for example, a conductive material such as aluminum.

An insulating material, which is a solder resist 29 having a predetermined film thickness, is formed on the surface of the package substrate 16. The solder resist 29 includes a thick film portion 29a that extends along the contour of the package substrate 16 on the surface of the package substrate 16 and a thin film portion 29b that is inside the thick film portion 29a. The film thickness of the thick film portion 29a is greater than that of the thin film portion 29b. The film thickness of the thin film portion 29b measured from the surface of the package substrate 16 is equal to the height of the conductive pads 23. As a result, a top surface 31 connected to the pad surfaces 25 is formed on the thin film portion 29b. The top surface 31 is disposed in the imaginary plane 26. The solder resist 29 is formed of an insulating resin material such as a photosensitive epoxy resin.

The conductive bumps 27 are sealed on the package substrate 16. The space between the LSI device 22 and the package substrate 16 in which the conductive bumps 27 are present is filled with an underfill material 32, which is a solid sealant. The underfill material 32 is, for example, a thermosetting resin material such as an epoxy resin. The resin material contains an inorganic filler such as silica. For example, the inorganic filler has a particle diameter of approximately 5 The underfill material 32 fixes the LSI device 22 to the surface of the package substrate 16. As a result, the LSI device 22 and the package substrate 16 are electrically connected to each other.

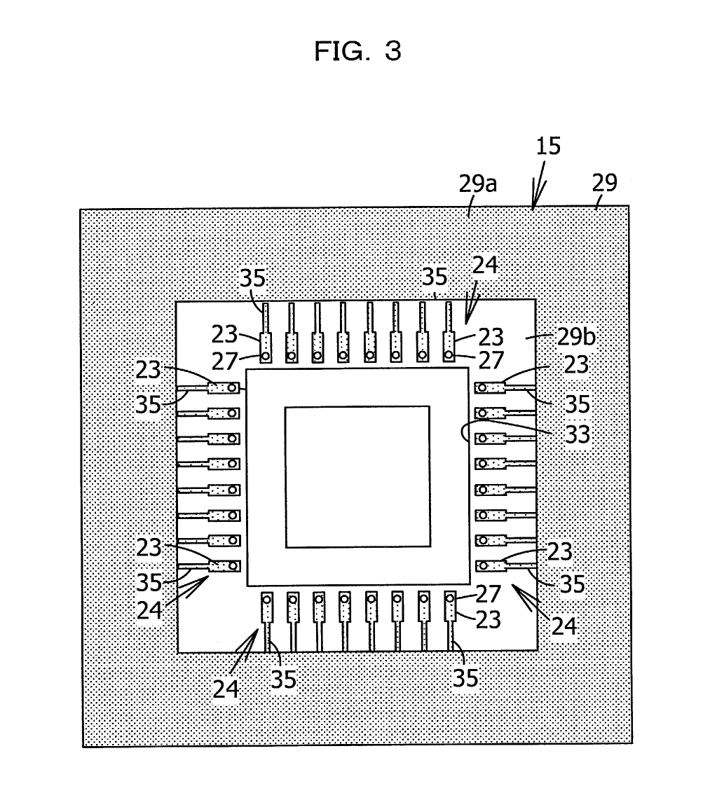

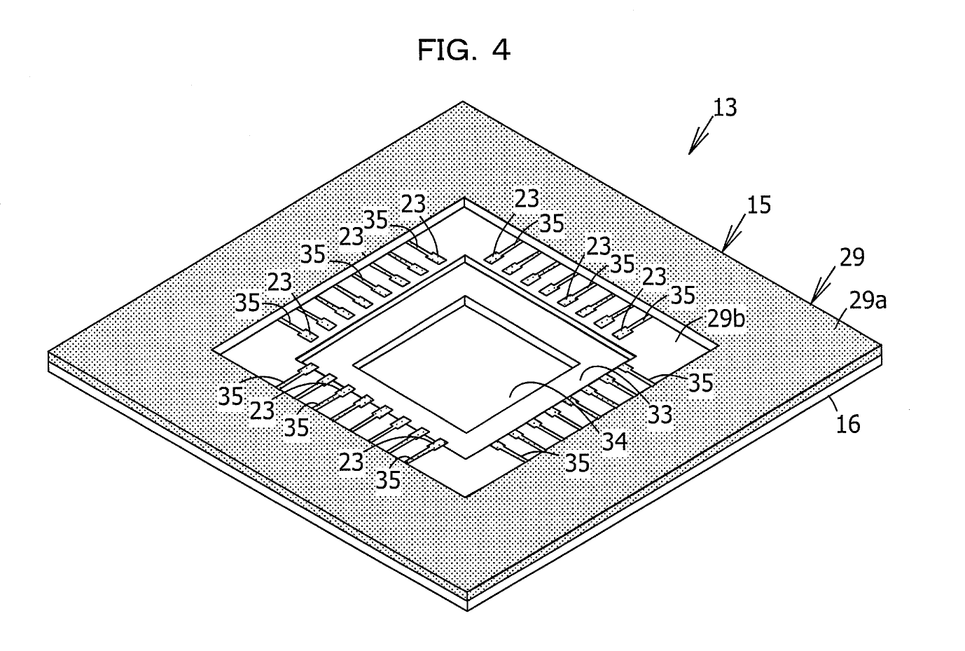

As illustrated in FIG. 3, the pad groups 24 are individually formed along four lines of the contour of the LSI device 22 between the LSI device 22 and the package substrate 16. Two of the pad groups 24 are parallel to each other, and the other two of the pad groups 24 are parallel to each other. For example, a rectangular opening 33 is formed in the thin film portion 29b of the solder resist 29 so that the opening 33 is inside the pad groups 24. In the opening 33, the surface of the package substrate 16 is exposed. Referring to FIG. 4, a depression 34 having a predetermined depth from the surface of the package substrate 16 is formed in the package substrate 16 in the opening 33. The depression 34 has, for example, a rectangular contour. The bottom surface of the depression 34 is parallel to the imaginary plane 26 (depicted in FIG. 2, for example). The depression 34 opens towards the undersurface of the LSI device 22.

Wiring patterns 35 that are individually connected to the conductive pads 23 are formed on the surface of the package substrate 16. The wiring pattern 35 externally extends from the outer end of the conductive pad 23 towards the outer contour of the package substrate 16. The conductive pads 23 and the wiring patterns 35 are embedded in the thin film portion 29b. The height of the wiring patterns 35 measured from the surface of the package substrate 16 is equal to that of the conductive pads 23. The height of the wiring patterns 35 measured from the surface of the package substrate 16 is equal to the film thickness of the thin film portion 29b. The wiring patterns 35 extend towards the thick film portion 29a of the solder resist 29. The wiring pattern 35 is connected to the conductive pad 19 via, for example, a through hole. The wiring patterns 35 are formed of a conductive material such as copper.

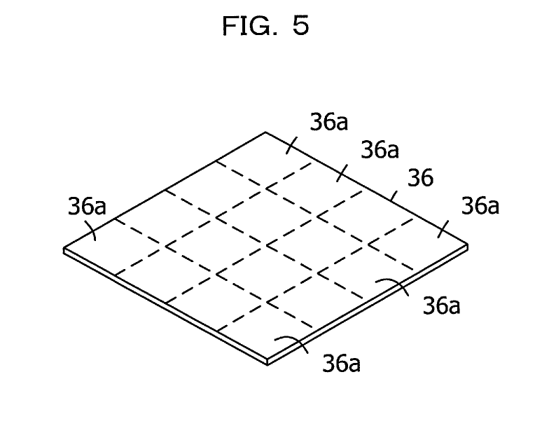

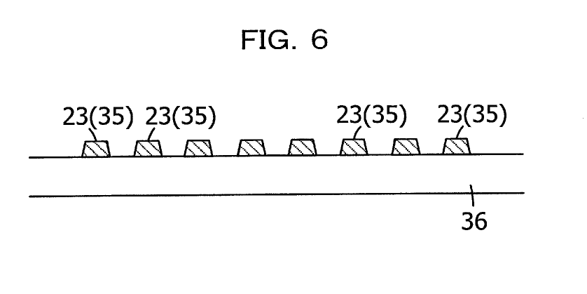

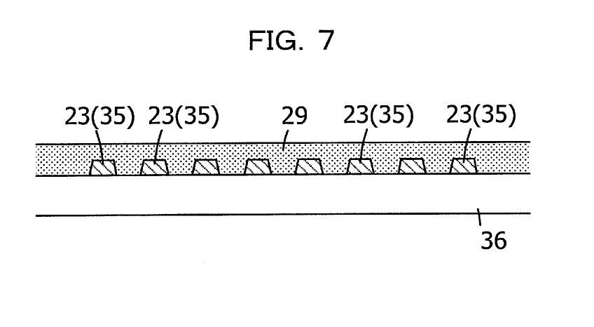

Next, a method of manufacturing the LSI package 15 will be described. First, a large package substrate 36 is prepared as illustrated in FIG. 5. On the package substrate 36, a plurality of mount regions 36a for the LSI device 22 are formed. As illustrated in FIG. 6, in each of the mount regions 36a on the surface of the package substrate 36, for example, the conductive pads 23 and the wiring patterns 35 are formed by electroless plating processing and electroplating processing. Subsequently, as illustrated in FIG. 7, the liquid solder resist 29 is applied to the whole area of the surface of the package substrate 36. The conductive pads 23 and the wiring patterns 35 are covered with the solder resist 29. An exposure and development process is then performed upon the solder resist 29 on the surface of the package substrate 36, and an unexposed portion of the solder resist 29 is removed.

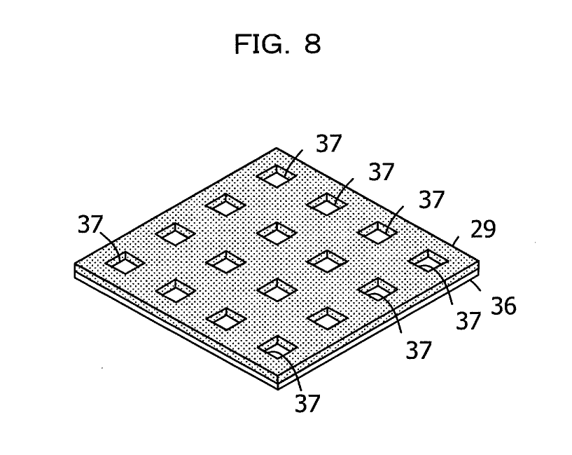

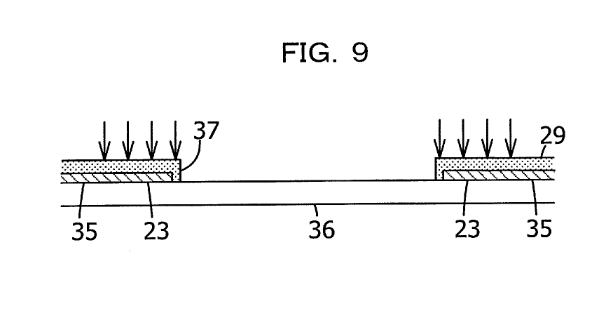

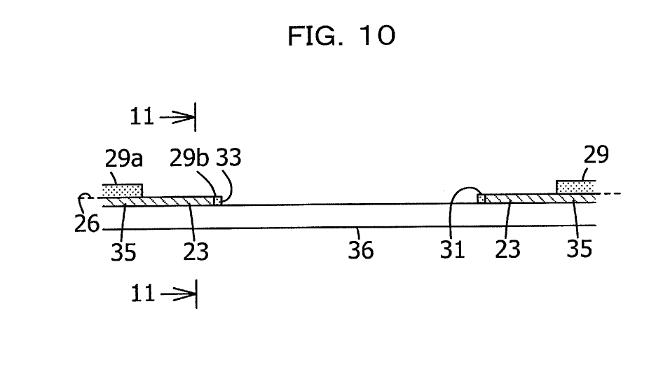

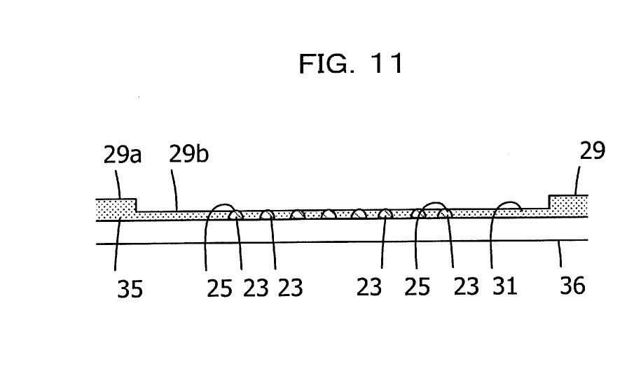

On the other hand, as illustrated in FIG. 8, air gaps 37 corresponding to the openings 33 are formed in the solder resist 29 cured by exposure. In the air gaps 37, the surface of the package substrate 36 is exposed. As illustrated in FIG. 9, for example, wet blasting processing is performed upon the solder resist 29 in a predetermined region along the contour of each of the air gaps 37. As a result, as illustrated in FIG. 10, the solder resist 29 is removed from the predetermined region. Thus, the thin film portion 29b and the opening 33 are formed. As illustrated in FIG. 11, the top surface 31 is specified at the upper end of the thin film portion 29b. The solder resist 29 is disposed between the conductive pads 23. The conductive pads 23 individually have the pad surfaces 25 at the upper ends thereof. The top surface 31 of the thin film portion 29b and the pad surfaces 25 of the conductive pads 23 are disposed in the common imaginary plane 26.

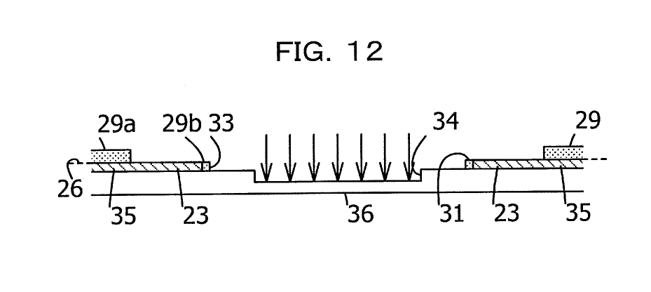

As illustrated in FIG. 12, in each of the mount regions 36a, wet blasting processing is performed upon a predetermined region on the surface of the package substrate 36 exposed in the air gap 37. The predetermined region of the package substrate 36 is removed by the wet blasting processing. As a result, the depression 34 is formed in the surface of the package substrate 36. Instead of the wet blasting processing, for example, cutting processing may be performed with an end mill. Subsequently, in each of the mount regions 36a, the liquid underfill material 32 is applied to the surface of the package substrate 36 inside the thick film portion 29a. The underfill material 32 contains an inorganic filler such as silica.

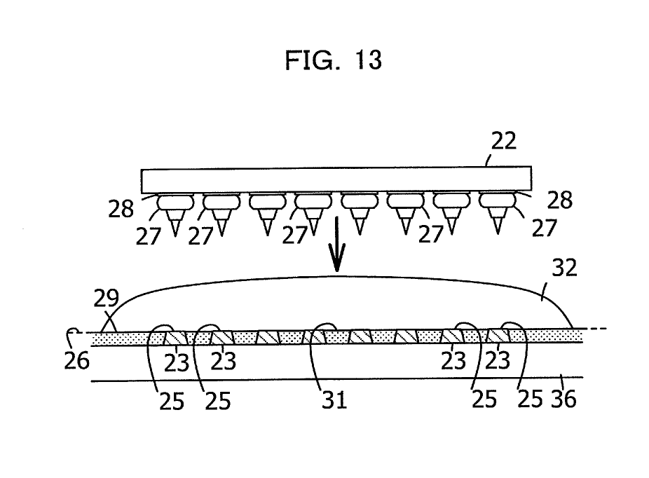

As illustrated in FIG. 13, in each of the mount regions 36a (depicted in FIG. 5) of the package substrate 36, an LSI device 22 is disposed. On the undersurface of the LSI device 22, the conductive pads 28 are formed. The conductive bumps 27 are individually bonded to the conductive pads 28 in advance by, for example, ultrasonic bonding. As is well known, when the conductive bumps 27 are individually bonded to the conductive pads 28, tapered tips of the conductive bumps 27 are formed. The LSI devices 22 are individually disposed in the mount regions 36a of the package substrate 36. Subsequently, when the LSI device 22 moves down, the conductive bumps 27 are individually received on the conductive pads 23 of the package substrate 36. Thus, the underfill material 32 is sandwiched between the surface of the package substrate 36 and the undersurface of the LSI device 22.

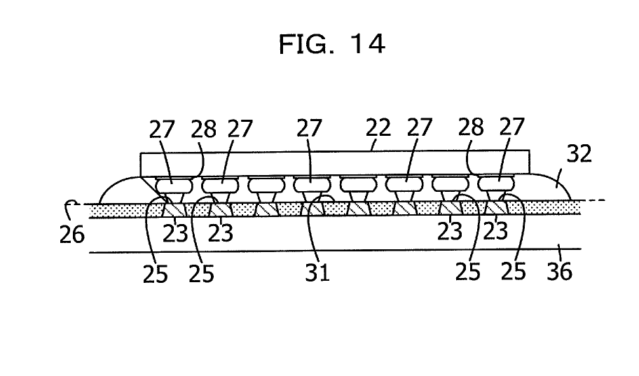

As illustrated in FIG. 14, the LSI device 22 is pressed against the surface of the package substrate 36 with a predetermined pressing force. The tapered tips of the conductive bumps 27 are crushed between the LSI device 22 and the conductive pads 23. At that time, heat processing is performed upon the LSI device 22 and the package substrate 36. The underfill material 32 is heated to a predetermined temperature equal to or higher than the curing temperature of the underfill material 32. As a result, the underfill material 32 is cured. The LSI device 22 is fixed to the surface of the package substrate 36 by curing of the underfill material 32. Subsequently, the package substrate 16, that is a part of the LSI package 15, is cut from the package substrate 36 for each of the LSI devices 22. Thus, the LSI package 15 is manufactured.

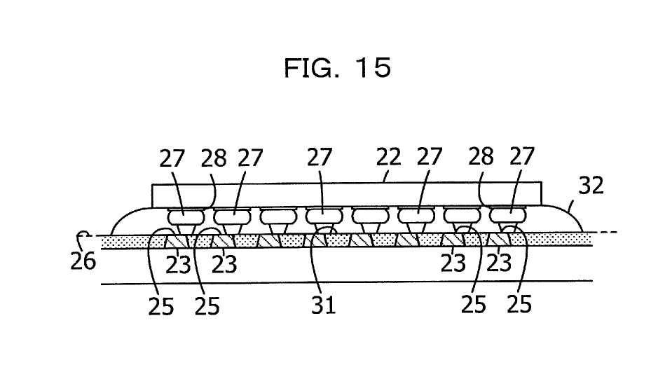

In the LSI package 15, the solder resist 29 is disposed between the conductive pads 23 on the package substrate 16. The pad surfaces 25 of the conductive pads 23 and the top surface 31 of the solder resist 29 are disposed in the common imaginary plane 26. Accordingly, as illustrated in FIG. 15, even if the position of the LSI device 22 with respect to the package substrate 16 is displaced from a predetermined position to a position parallel to the surface of the package substrate 16, the tips of the conductive bumps 27 are received by, for example, both of the pad surfaces 25 of the conductive pads 23 and the top surface 31 of the solder resist 29. Thus, it is possible to prevent the conductive bumps 27 from falling between the conductive pads 23 with certainty. As a result, irrespective of the displacement of the positions of the conductive bumps 27, the conductive bumps 27 are individually bonded to the conductive pads 23 with certainty.

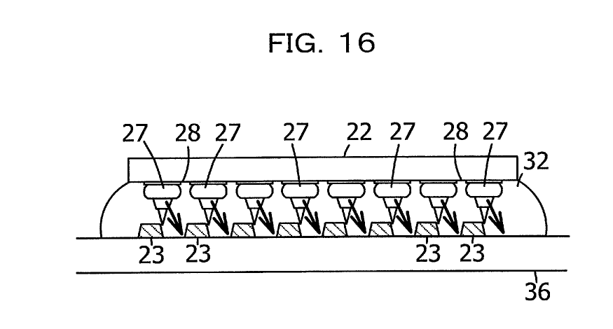

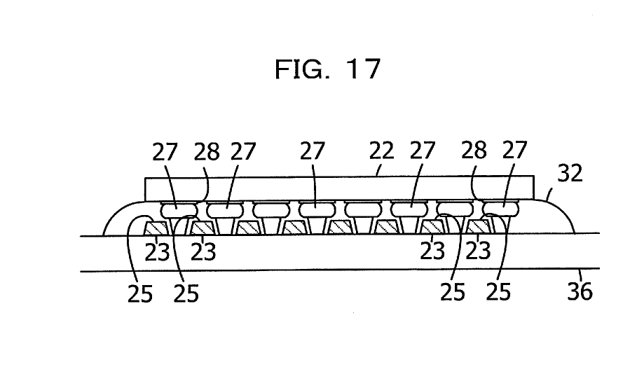

On the other hand, it is assumed that the solder resist 29, more specifically the thin film portion 29b, is not formed on the surface of the package substrate 16. As illustrated in FIG. 16, when the position of the LSI device 22 with respect to the package substrate 16 is displaced from a predetermined position to a position parallel to the surface of the package substrate 16, the tips of the conductive bumps 27 individually slip along side surfaces of the conductive pads 23 that are bonding targets. Each of the conductive bumps 27 falls between the conductive pads 23. As a result, as illustrated in FIG. 17, for example, the tips of the conductive bumps 27 are received on the surface of the package substrate 16 between conductive pads 23. In such a case, a poor connection between the conductive bump 27 and the conductive pad 23 that is a bonding target occurs. When the amount of displacement is large, the conductive bump 27 is improperly connected to the conductive pad 23 that is not the bonding target.

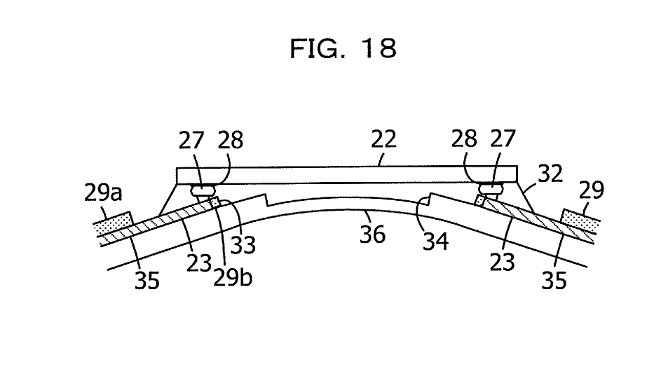

The LSI device 22 on the motherboard 13 produces heat during operation. The heat production causes a thermal expansion of the package substrate 16 and the LSI device 22. The thermal expansion coefficient of the package substrate 16 formed of a resin is approximately four times that of the LSI device 22 formed of silicon. Accordingly, as illustrated in FIG. 18, warpage of the package substrate 16 occurs. The distance between the undersurface of the LSI device 22 and the surface of the package substrate 16 is reduced between the pad groups 24. Since the depression 34 facing the undersurface of the LSI device 22 is formed in the package substrate 16, an inorganic filler contained in the underfill material 32 is prevented from contacting the LSI device 22 between the package substrate 16 and the LSI device 22. Thus, it is possible to prevent the damage to the undersurface of the LSI device 22.

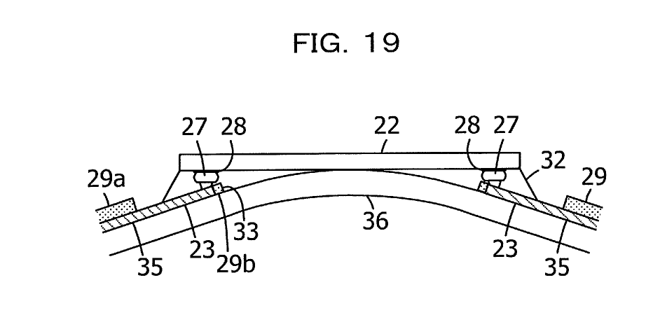

As compared with a case in which the depression 34 is formed in the surface of the package substrate 16, when the depression 34 is not formed in the surface of the package substrate 16, the distance between the package substrate 16 and the LSI device 22 is reduced by the depth of the depression 34. As illustrated in FIG. 19, it can be assumed that warpage of the package substrate 16 occurs and the surface of the package substrate 16 contacts the undersurface of the LSI device 22. As a result, an inorganic filler contained in the underfill material 32 is sandwiched between the package substrate 16 and the LSI device 22. In addition, the inorganic filler collides against the undersurface of the LSI device 22, so that the undersurface of the LSI device 22 is damaged. The LSI device 22 may break as a result. With the current reduction in the thickness of the LSI package 15, the distance between the LSI device 22 and the package substrate 16 tends to decrease. Accordingly, the operational effect of the present invention becomes more pronounced.

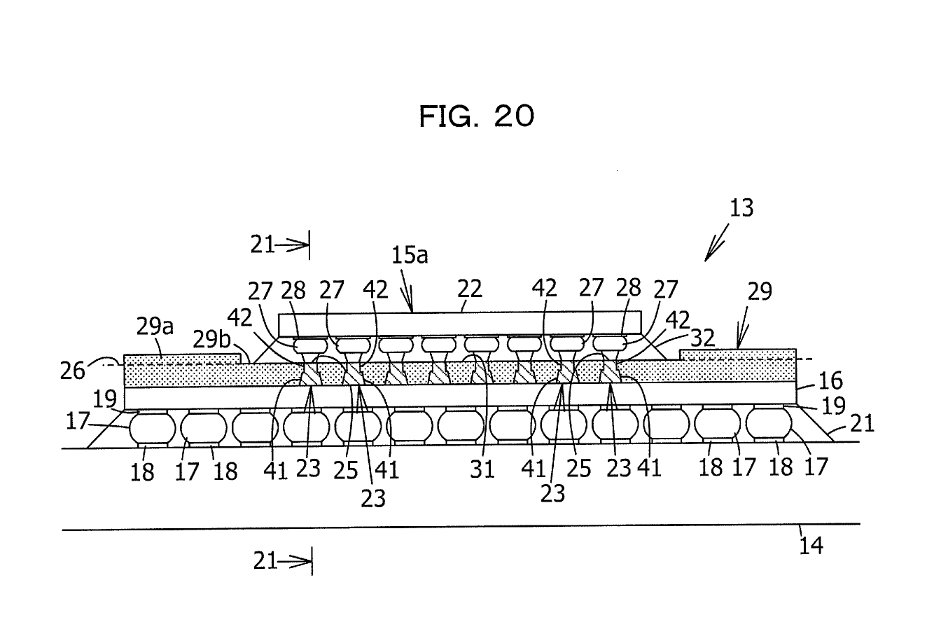

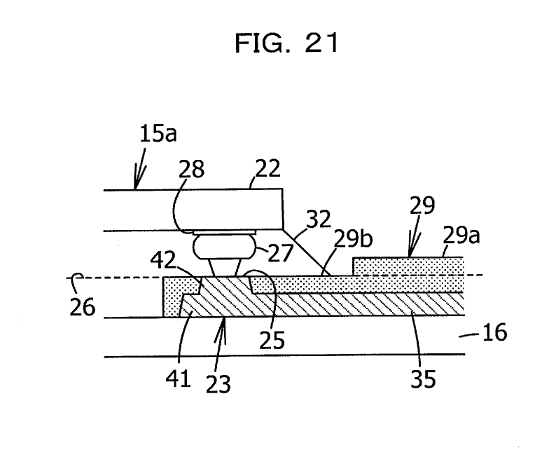

FIG. 20 is a schematic cross-sectional view illustrating a configuration of an LSI package 15a according to a second embodiment of the present invention. In the LSI package 15a, each of the conductive pads 23 includes a pad body 41 disposed on the surface of the package substrate 16 and a protrusion portion 42 disposed on the pad body 41. The pad body 41 corresponds to the conductive pad 23 according to the first embodiment of the present invention. At the upper end of the protrusion portion 42, the pad surface 25 is formed. The protrusion portion 42 is formed of a conductive material such as copper. The solder resist 29 is disposed between the protrusion portions 42. The top surface 31 of the solder resist 29 is disposed in the imaginary plane 26. Referring to FIG. 21, the height from the surface of the package substrate 16 to the pad surface 25 of the protrusion portion 42 is greater than that of the pad body 41 and the wiring pattern 35. The depression 34 is not formed in the surface of the package substrate 16.

In the LSI package 15a, the protrusion portions 42 increase the distance between the undersurface of the LSI device 22 and the surface of the package substrate 16. As a result, even if the difference between the heat expansion coefficient of the LSI device 22 and the heat expansion coefficient of the package substrate 16 causes the warpage of the package substrate 16, it is possible to prevent an inorganic filler contained in the underfill material 32 from contacting the LSI device 22 between the package substrate 16 and the LSI device 22. As a result, the damage to the undersurface of the LSI device 22 can be prevented. Furthermore, in the LSI package 15a, an operational effect similar to the above-described operational effect can be achieved. In the LSI packages 15 and 15a, like or corresponding parts are denoted by like or corresponding reference numerals.

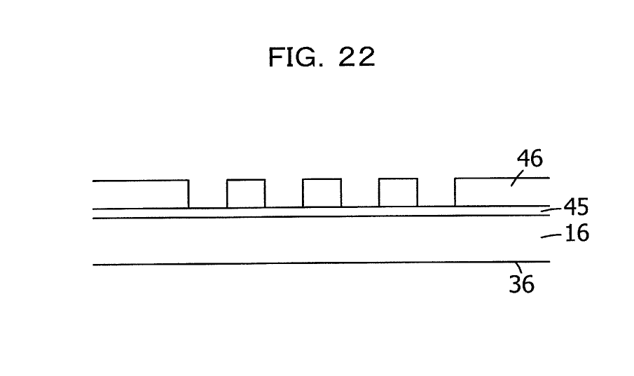

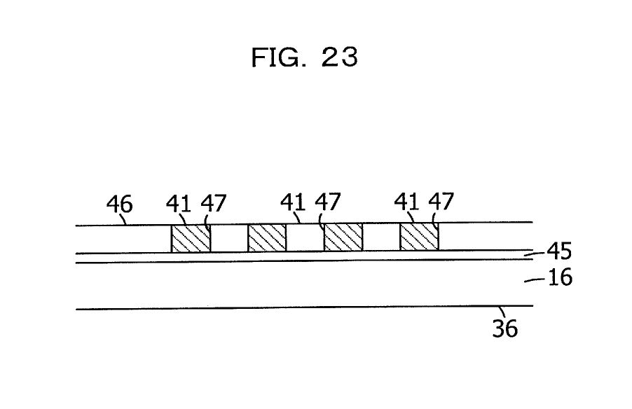

Next, a method of manufacturing the LSI package 15a will be described. Like in the first embodiment, the conductive pads 23 and the wiring patterns 35 are formed on the package substrate 36. As illustrated in FIG. 22, a thin film 45 made of copper is formed on the surface of the package substrate 36 by electroless plating processing. The thin film 45 covers the surface of the package substrate 36. A dry film resist 46 is formed on the surface of the thin film 45 by predetermined patterning. In the dry film resist 46, air gaps 47 forming the contours of the pad body 41 and the wiring pattern 35 are formed. As illustrated in FIG. 23, on the surface of the package substrate 36, the pad body 41 and the wiring pattern 35 are formed in the air gap 47 by electroplating processing with copper. Subsequently, the dry film resist 46 is removed.

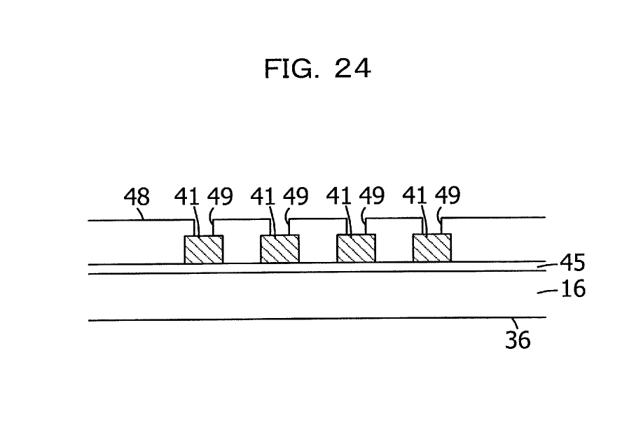

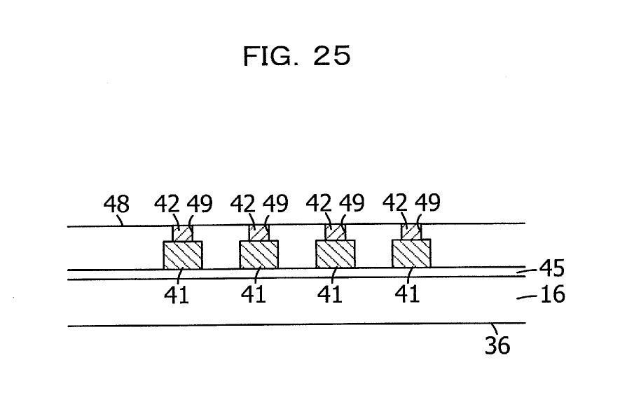

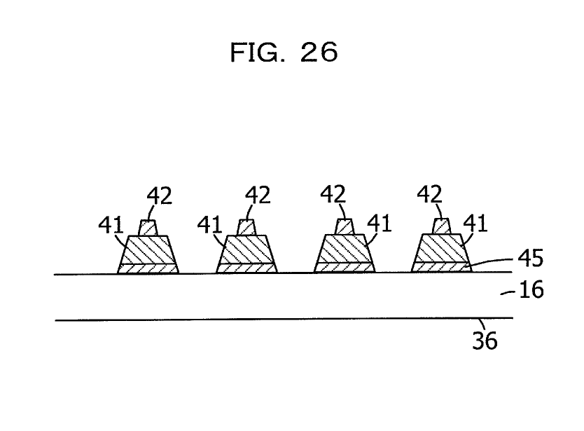

As illustrated in FIG. 24, a dry film resist 48 is formed on the surface of the package substrate 36 by predetermined patterning. In the dry film resist 48, air gaps 49 forming the contours of the protrusion portions 42 are formed. As illustrated in FIG. 25, on the surface of the package substrate 36, the protrusion portions 42 are individually formed in the air gaps 49 by electroplating processing with copper. Subsequently, the dry film resist 48 is removed. After the dry film resist 48 has been removed, as illustrated in FIG. 26, the thin film 45 is removed from the surface of the package substrate 36 outside the contours of the conductive pads 23 and the wiring patterns 35 by etching processing. Thus, the conductive pads 23 and the wiring patterns 35 are formed. In the etching processing, a resist (not illustrated) may be formed on the conductive pads 23 and the wiring patterns 35. Subsequently, like in the first embodiment of the present invention, the process from the formation of the solder resist 29 to the cutting of the package substrate 16 is performed.

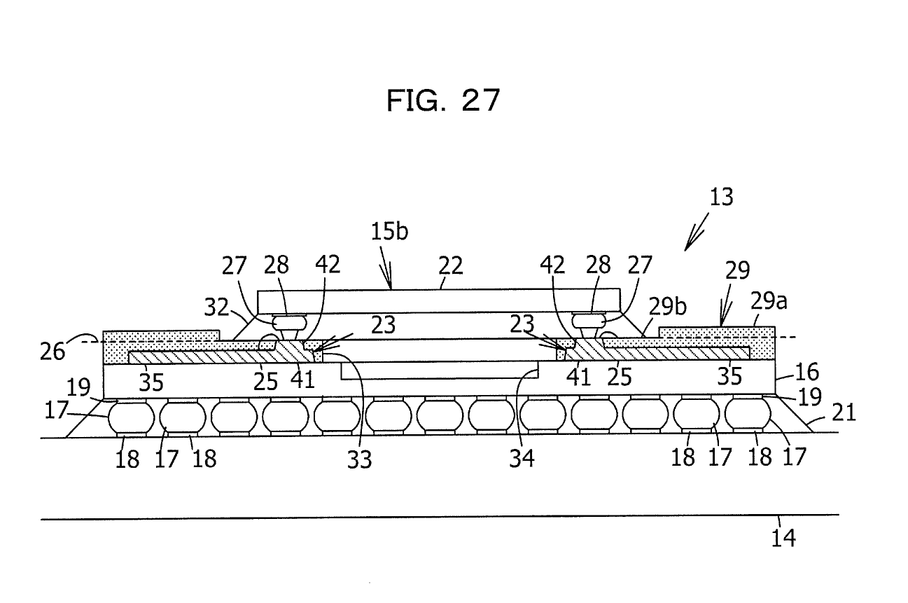

FIG. 27 is a schematic cross-sectional view illustrating a configuration of an LSI package 15b according to a third embodiment of the present invention. The LSI package 15b is obtained by forming the depression 34 in the surface of the package substrate 16 in the LSI package 15a. The depression 34 further increases the distance between the LSI device 22 and the package substrate 16 as compared with the LSI package 15a. As a result, even if the warpage of the package substrate 16 occurs, it is possible to prevent an inorganic filler contained in the underfill material 32 from contacting the LSI device 22 between the package substrate 16 and the LSI device 22. The damage to the undersurface of the LSI device 22 can be therefore prevented. In the LSI package 15b, an operational effect similar to those obtained in the first and second embodiments of the present invention can be achieved. In the LSI packages 15, 15a, and 15b, like or corresponding parts are denoted by like or corresponding reference numerals.

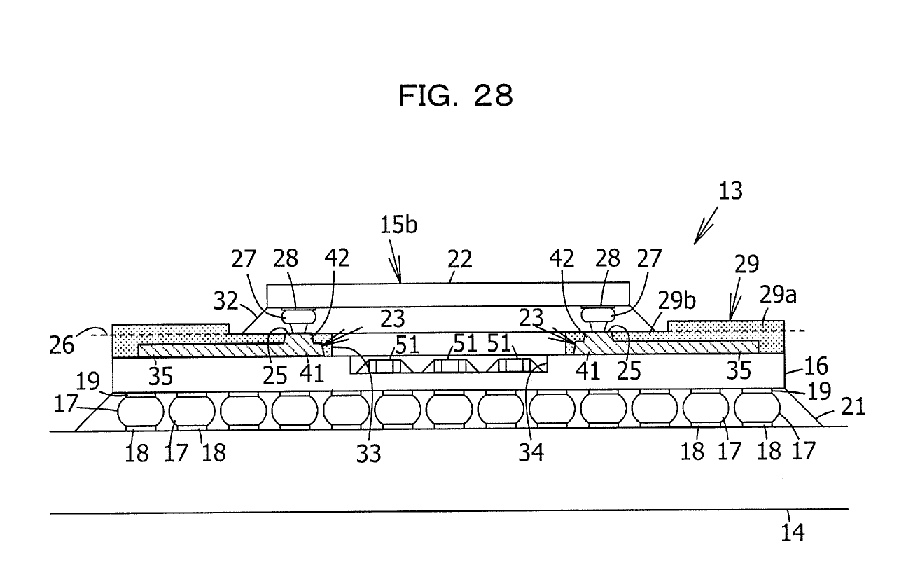

FIG. 28 is a schematic cross-sectional view illustrating a configuration of an LSI package 15c according to a fourth embodiment of the present invention. The LSI package 15c is obtained by mounting electronic components 51 on the bottom surface of the depression 34 in the LSI package 15b. It is desirable that the height of the electronic components 51 measured from the bottom surface of the depression 34 be less than the depth of the depression 34. The electronic component 51 includes, for example, an element capacitor and an element resistor. On the bottom surface of the depression 34, the electronic components 51 may be bonded to conductive pads (not illustrated) formed on the package substrate 16 with, for example, a solder material. In the LSI packages 15 to 15c, like or corresponding parts are denoted by like or corresponding reference numerals.

In the LSI package 15c, the electronic components 51, which are mounted on the surface of the package substrate 16 outside the contour of the LSI device 22 in the related art, are mounted on the surface of the package substrate 16 inside the contour of the LSI device 22. As a result, it is possible to reduce the area of the surface of the package substrate 16 outside the contour of the LSI device 22. This contributes to the miniaturization of the LSI package 15c. When the height of the electronic components 51 is less than the depth of the depression 34, it is possible to prevent the electronic components 51 from contacting the LSI device 22 irrespective of the warpage of the package substrate 16. The damage to the undersurface of the LSI device 22 can be therefore prevented. In the LSI package 15c, an operational effect similar to those obtained in the first to third embodiments of the present invention can be achieved.

All examples and conditional language provided herein are intended for the pedagogical objects of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although various embodiments of the invention have been described in detail, it will be understood by those of ordinary skill in the relevant art that various changes, substitutions, and alterations could be made hereto without departing from the spirit and scope of the invention as set forth in the claims.

1. (canceled)

2. (canceled)

3. An electronic component manufacture method, comprising:
disposing a plurality of conductive pads on a package substrate;
disposing an insulating material between the plurality of conductive pads such that a top surface of the insulating material is located on an identical plane to an upper surface of the plurality of conductive pads; and
aligning a conductive bump of a semiconductor device on a corresponding conductive pad of the plurality of conductive pads.

4. The electronic component manufacture method according to claim 3, further comprising forming a depression in the package substrate so as to face the semiconductor device, wherein the plurality of conductive pads are disposed outside the depression.

5-9. (canceled)

10. An electronic component manufacture method, comprising:
forming a depression in a package substrate;
disposing a plurality of conductive pads outside the depression; and
aligning a conductive bump of a semiconductor device on a corresponding conductive pad of the plurality of conductive pads.

11. The electronic component manufacture method according to claim 10, further comprising forming a protrusion portion on the plurality of conductive pads, the protrusion portion having a narrower width than each of the plurality of conductive pads.

12. The electronic component manufacture method according to claim 11, further comprising disposing an insulating material between the plurality of conductive pads such that a top surface of the insulating material is located on an identical plane to an upper surface of the protrusion portion.
